(19) United States
(12) Patent Application Publication
(10) Pub. No.: US 2023/0411413 A1
(43) Pub. Date: Dec. 21, 2023

(54) STRUCTURE AND METHOD FOR IMPROVING NEAR-INFRARED QUANTUM EFFICIENCY OF BACKSIDE ILLUMINATED IMAGE SENSOR

(71) Applicant: Shanghai Huali Integrated Circuit Corporation, Shanghai (CN)

(72) Inventors: Chunshan Zhao, Shanghai (CN); Wuzhi Zhang, Shanghai (CN); Yamin Cao, Shanghai (CN); Wei Zhou, Shanghai (CN); Yansheng Wang, Shanghai (CN)

(21) Appl. No.: 18/129,330

(22) Filed: Mar. 31, 2023

(30) Foreign Application Priority Data
Jun. 21, 2022 (CN) 202210702800.2

(51) Int. Cl. H01L 27/146

(52) U.S. Cl. CPC H01L 27/14603; H01L 27/14645; H01L 27/14621; H01L 27/14627; H01L 27/1464; H01L 27/14685

(57) ABSTRACT

The present application provides a structure and method for improving near-infrared quantum efficiency of a backside illuminated image sensor. The structure includes a substrate and a plurality of photodiodes. The photodiodes are formed in the substrate. A cell deep trench isolation structure is fabricated on a surface of each photodiode. The cross section of the cell deep trench isolation structure 3 parallel to the surface of said photodiode comprises one or both of a four-quadrant square shape and a Union Jack shape. In the present application, by fabricating the cell deep trench isolation structures on the surface of each photodiode, the cell deep trench isolation structures increase light scattering in the photodiode, thus the optical path is increased, thereby improving the absorption of incident light, especially in near-infrared wavelength. As a result the quantum efficiency and sensor's imaging quality are improved.

### CROSS-REFERENCES TO RELATED APPLICATIONS

This application claims priority to Chinese patent application No. CN 202210702800.2, filed on Jun. 21, 2022 at CNIPA, and entitled “STRUCTURE AND METHOD FOR IMPROVING NEAR-INFRARED QUANTUM EFFICIENCY OF BACKSIDE ILLUMINATED IMAGE SENSO”, the disclosure of which is incorporated herein by reference in entirety.

### TECHNICAL FIELD

The present application is related to the technical field of semiconductor image sensors, in particular, to a structure and method for improving near-infrared quantum efficiency of a backside illuminated image sensor.

### BACKGROUND

CMOS image sensors can be categorized into two types, i.e., the Frontside Illuminated Image Sensors (FSI CISs) and the Backside Illuminated CMOS Image Sensors (BSI CISs) depending on where incident light enters the photodiodes. The frontside illuminated image sensors are image sensors in which incident light enters the photodiodes from the front side of the silicon substrate of the CMOS image sensor. The backside illuminated image sensors are image sensors in which incident light enters the photodiodes from the back side of the silicon substrate of the CMOS image sensor. Specifically in a backside illuminated image sensors, after the silicon substrate is thinned, a color filter (CF) and a micro lens are built on the back side of photodiodes. As light enters from the back side, the photosensitive area of the photoelectric element is increased, loss of light through wiring decreases, thus greatly improving the photosensitive ability of CIS even if it is under a weak light environment, and the sensitivity of the pixel unit. In addition, the backside illuminated structure has the advantage that it is more suitable for small pixels because it is easier to be integrated into the conventional semiconductor process. So with the higher integration level, the cost is reduced, so as well as the device size.

An human eye is sensitive to the electromagnetic waves at wavelength in the range of 400 nm-700 nm. The wavelength band in the range of 700 nm-2500 nm is near-infrared (NIR) light. responds The maximum wavelength a silicon-based CMOS can respond is about 1100 nm. Applications in the near-infrared band include security cameras protecting night safety and medical care devices.

An image sensor gets energy from incident photons which then generate electron-hole pairs in the photoactive surface layer. Quantum Efficiency (QE) measures the photoelectric conversion efficiency of a photoelectric device, is an indicator of the electric photosensitivity of the photosensitive device. Photoelectric conversion efficiency refers to the ratio of photocurrent generated by the number of photons incident on the device. Therefore the photoelectric conversion efficiency can be quantified through quantum efficiency. Generally speaking, higher the quantum efficiency leads to, higher imaging quality of a CMOS sensor. The quantum efficiency of existing backside illuminated CMOS sensors is better than that of the traditional frontside illuminated CMOS sensor. However, increasingly users are not satisfied with the imaging quality of the existing backside illuminated CMOS sensor, especially in some special applications, such as the night vision security cameras, vehicle-mounted high-end chips and military devices. Therefore, device quantum efficiency at the near-infrared band can no longer meet users needs. To obtain higher imaging quality, it is necessary to improve the quantum conversion efficiency of the backside illuminated image CMOS sensors.

### BRIEF SUMMARY

The present application provides a structure and method for improving near-infrared quantum efficiency of a backside illuminated image sensor.

The present application provides a backside illuminated image sensor structure, which includes a substrate and a plurality of photodiodes, the photodiodes are formed in the substrate, and a cell deep trench isolation structure is fabricated on a surface of each of the photodiodes.

The cross section of the cell deep trench isolation structure parallel to the surface of said photodiode comprises one or both of a four-quadrant square shape and a Union Jack shape.

In an optimized example of the structure of the backside illuminated image sensor according to the present application, the depth of the cell deep trench isolation structure is between 0.3 μm and 1.5 μmm, and the critical dimension of the cell is between 100 nm and 200 nm.

In an optimized example, the photodiodes are isolated from each other by deep trench isolation regions, and the depth of each cell deep trench isolation structure is less than the depth of each deep trench isolation region.

In an optimized example, the structure further includes a color filter and a micro lens sequentially disposed on one surface of the photodiode, and a metal wire structure discposed on the other surface of the photodiode.

The present application further provides a method for improving near-infrared quantum efficiency of the backside illuminated image sensor, wherein the method at least includes:
providing a substrate and fabricating a plurality of photodiodes in the substrate; and
fabricating a cell deep trench isolation structure on a surface of each photodiode.

In an optimized example, the cross section of the cell deep trench isolation structure parallel to the surface of said photodiode comprises one or both of a four-quadrant square shape and a Union Jack shape.

In an optimized example, the depth of the cell deep trench isolation structure is between 0.3 μm and 1.5 μm, and the structure's characteristic size is between 100 nm and 200 nm.

In an optimized example, the cell deep trench isolation structure is fabricated on the surface of each photodiode by applying photolithographic and etching processes.

In an optimized example, the method further includes a step of forming a deep trench isolation region between two adjacent photodiodes, and the depth of the cell deep trench isolation structure is less than the depth of the deep trench isolation region.

In an optimized example, the method further includes:
forming a color filter and micro lens sequentially on one surface of the photodiode; and
forming a metal wire structure on the other surface of the photodiode.

As described, the structure at least includes a substrate and a plurality of photodiodes. The photodiodes are formed in the substrate. A cell deep trench isolation structure is fabricated on the surface of each photodiode. The cross section of the cell deep trench isolation structure 3 parallel to the surface of said photodiode comprises one or both of a four-quadrant square shape and a Union Jack shape. In the present application, by fabricating the cell deep trench isolation structures on surfaces of photodiodes, the cell deep trench isolation structures can increase light scattering in the photodiodes, thus enlarger the optical path, increasing the absorption of incident light, especially the near-infrared light, so greatly improving the quantum efficiency and photographing quality of the devices.

### BRIEF DESCRIPTION OF THE DRAWINGS

FIG. 1 to FIG. 4 illustrate schematic diagrams of structures following major steps during applying a method for making a backside illuminated image sensor according to an embodiment of the present application. FIG. 4 illustrates a cross sectional view of the structure of the backside illuminated image sensor according to an embodiment.

FIG. 5 illustrates a top view of a cell deep trench isolation structure with a four-quadrant square shape in the present application.

FIG. 6 illustrates a top view of a cell deep trench isolation structure with a Union Jack shape in the present application.

FIG. 7 illustrates a comparison chart of simulated quantum efficiencies of the four image sensors.

### DESCRIPTION OF REFERENCE NUMERALS

1 substrate
2 photodiode
3 cell deep trench isolation structure
4 deep trench isolation region
5 color filter
6 micro lens
7 metal wire structure

### DETAILED DESCRIPTION OF THE APPLICATION

The embodiments of the present application will be described below through specific examples. Those skilled in the art can easily understand other advantages and effects of the present application from the content disclosed in the description. The present application may also be implemented or applied in other specific ways. The details in the description may also be modified or changed based on different views and applications without departing from the spirit of the present application.

Please refer to the drawings. it should be noted that the drawings provided in the embodiments only illustrate the basic concept of the present application in a schematic way, thus only illustrate the components related to the present application, and are not drawn according to the number, shape and size of the components in the actual implementation. The type, number and scale of each component in the actual implementation may be changed freely, and the layout configuration of the component may be more complex.

### Embodiment 1

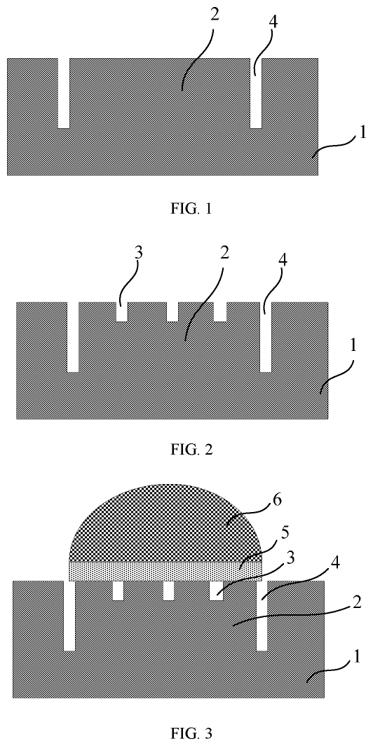

FIG. 1 illustrates a structure which includes a substrate 1 and a plurality of photodiodes 2. The photodiodes 2 are formed in the substrate 1. A Cell Deep Trench Isolation (CDTI) structure 3 and a deep trench isolation region(DTI) are fabricated in a surface of each photodiode 2.

As an optimized example, the cross section of the cell deep trench isolation structure parallel to the surface of said photodiode comprises one or both of a four-quadrant square shape and a Union Jack shape. FIG. 5 shows an SEM image of the cell deep trench isolation structure 3 with a four-quadrant square shape. FIG. 6 shows an SEM image of the cell deep trench isolation structure 3 with a Union Jack shape. In the specific example, the cell deep trench isolation structure 3 is selected to have top view of a four-quadrant square shape or a Union Jack shape, preferably a Union Jack shape.

As an example, the depth of the cell deep trench isolation structure 3 is between 0.3 μm and 1.5 μm, and the critical dimension (CD) is between 100 nm and 200 nm. In another example, the depth of the cell deep trench isolation structure 3 is about 0.5 μm, and the critical dimension is 120 nm. In another example, the depth of the cell deep trench isolation structure 3 is about 0.8 μm, and the critical dimension is 150 nm. In another example, the depth of the cell deep trench isolation structure 3 is 0.8 μm, and the critical dimension is 150 nm.

The cell deep trench isolation structure 3 increases light scattering, thus extends the optical path, thereby improving the quantum efficiency of light in the near-infrared band.

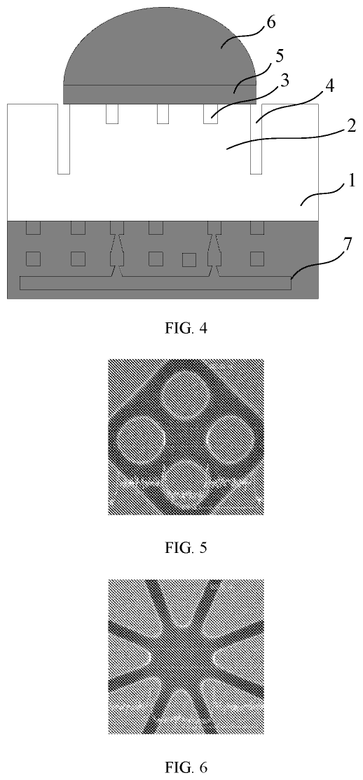

As an example, referring to FIG. 4, the photodiodes 2 are isolated from each other by deep trench isolation (DTI) regions 4. The photodiodes 2 may form arrays in the substrate 1. The deep trench isolation regions 4 mainly play the role of isolating the photodiodes 2 from each other, thereby preventing inter-pixel crosstalk. so to improve imaging quality. The deep trench isolation region 4 has a relatively large depth (>2 μm), while the cell deep trench isolation structures 3 mainly play the role of scattering light, so they should not be deep. In general, the depth of the cell deep trench isolation structure 3 is less than the depth of the deep trench isolation region 4.

As an example, referring to FIG. 4, the structure further includes a color filter 5 and a micro lens 6 sequentially disposed on one surface of the photodiode 2 and a metal wire structure 7 disposed on the other surface of the photodiode. It should be noted that FIG. 4 only illustrates the color filter 5 and micro lens 6 on the surface of an exemplary photodiode 2, other photodiodes 2 may also have color filters 5 and micro lenses 6. The metal wire structure 7 can be used for connecting to an external structure.

Table 1 shows the measured quantum efficiency data of four image sensors. The four type of image sensors are respectively an image sensor without a cell deep trench isolation (CDTI) structure, an image sensor including a CDTI structure with a square shape, an image sensor including a CDTI structure with a four-quadrant square shape, and an image sensor including a CDTI structure with a Union Jack shape. Two samples are tested for each type of image sensors.

TABLE 1

| | | | | | CDTI with four- | | CDTI with | |
|---|---|---|---|---|---|---|---|---|
| sensor | | | CDTI with | | quadrant square | | Union Jack | |
| type | Without CDTI | | square shape | | shape | | shape | |
| Sample | Sample | Sample | Sample | Sample | Sample | Sample | Sample | Sample |
| # | 1 | 2 | 1 | 2 | 1 | 2 | 1 | 2 |
| λ = 850 nm | 20.0% | 19.5% | 27.5% | 26.0% | 37.1% | 36.0% | 47.9% | 46.5% |
| QE | | | | | | | | |
| λ = 940 nm | 8.0% | 7.8% | 15.7% | 15.0% | 23.1% | 22.9% | 28.8% | 27.5% |
| QE | | | | | | | | |

It can be seen from above that the Quantum Efficiency (QE) of the image sensors tested under the same condition is summarized below after taking the average of two samples:

For the image sensor without CDTI, the QE of wavelength 850 nm is 19.8% and the QE of wavelength 940 nm is 7.9%; for the image sensor including a CDTI structure with a square shape, the QE of wavelength 850 nm is 26.8% and the QE of wavelength 940 nm is for the image sensor including a CDTI structure with a four-quadrant square shape, the QE of wavelength 850 nm is 36.6% and the QE of wavelength 940 nm is 23.0%; for the image sensor including a CDTI structure with a Union Jack shape, the QE of wavelength 850 nm is 47.2% and the QE of wavelength 940 nm is 28.2%.

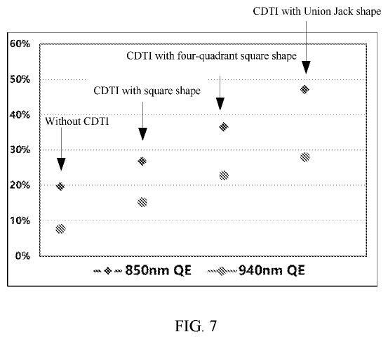

FIG. 7 plots the QEs of the four image sensors. Through comparison, it is concluded that the QE of wavelength 850 nm for the image sensor including a CDTI structure with the four-quadrant square shape has an improvement by 37% relative to the image sensor including a CDTI structure with a square shape, and the QE of wavelength 940 nm has an improvement by 49%; the QE of wavelength 850 nm of the image sensor including a CDTI structure with a Union Jack shape has an improvement by 76% relative to the image sensor including a CDTI structure with a square shape, and the QE of wavelength 940 nm has an improvement by 83%.

Clearly, image sensors in the backside illuminated near-infrared (NIR BSI) platform with the design of CDTI structures having the four-quadrant shape or having the Union Jack shape are more superior than other types.

In short, the design of CDTI structures provides a great impact on the optical path, and the QE varies greatly with different structures. Applying the disclosed QE improvement techniques, combined with the optimized CDTI designs like the four-quadrant square shape and a Union Jack shape, the image sensor performance can be greatly enhanced.

### Embodiment 2

Referring to FIG. 1 to FIG. 4, this embodiment provides a method for improving near-infrared quantum efficiency (QE) of a backside illuminated image sensor, through which the above disclosed structure can be obtained. The method at least includes the following steps:

Referring to FIG. 1, firstly step 1 is performed. That is, a substrate 1 is provided and a plurality of photodiodes 2 is fabricated in the substrate 1.

Referring to FIG. 2, then step 2 is performed. That is, cell deep trench isolation structures 3 are fabricated on a surface of each photodiode 2.

As an optimized example, the cross section of the cell deep trench isolation structure 3 parallel to the surface of said photodiode comprises one or both of a four-quadrant square shape and a Union Jack shape. FIG. 5 shows an SEM image of the cell deep trench isolation structure 3 with a four-quadrant square shape. FIG. shows an SEM image of the cell deep trench isolation structure 3 with a Union Jack shape. In the specific example the cell deep trench isolation structure 3 is selected to be a four-quadrant square shape or a Union Jack shape, preferably a Union Jack shape.

As an example, the depth of the cell deep trench isolation structure 3 is between 0.3 μm and 1.5 μm, and the critical dimension is between 100 nm and 200 nm. In an example, the depth of the cell deep trench isolation structure 3 is 0.5 μm, and the critical dimension is 120 nm. In another example, the depth of the cell deep trench isolation structure 3 is about and the critical dimension is about 150 nm. In another example, the depth of the cell deep trench isolation structure 3 is about 0.8 μm, and the critical dimension is about 150 nm.

The disclosed technique uses the cell deep trench isolation structures 3 to increase light scattering, thus extending the optical path and improving the quantum efficiency of light in the near-infrared wavelength band.

As an example, the cell deep trench isolation structure 3 may be fabricated on the surface of each photodiode 2 by adopting photolithographic and etching processes. The present application needs to adjust the photolithographic and etching process conditions according to different CDTI design structures to ensure the process window.

Referring to FIG. 1, the method further includes a step of forming a deep trench isolation region 4 between two of the adjacent photodiodes 2. The photodiodes 2 may be arranged in arrays in the substrate 1. The deep trench isolation region 4 mainly plays the role of isolating the photodiodes 2 from each other, thus preventing inter-pixel crosstalk, resulting in improving the imaging quality. The deep trench isolation region 4 has a relatively large depth (>2 μm), while the cell deep trench isolation structure 3 mainly plays the role of increasing light scattering, so they should not be deep. In general, the depth of the cell deep trench isolation structure 3 is less than the depth of the deep trench isolation region 4.

As an example, referring to FIG. 3 and FIG. 4, the method further includes the following steps:

Referring to FIG. 3, a color filter 5 and micro lens 6 are sequentially formed on one surface of the photodiode 2.

Referring to FIG. 4, a metal wire structure 7 is formed on the other surface of the photodiode 2.

It should be noted that FIG. 3 and FIG. 4 only illustrate the color filter 5 and micro lens 6 on the surface of one exemplary photodiode 2, but should apply to other photodiodes 2 as well. The metal wire structure 7 can be used for connecting to an external structure.

The improvement data and effects of the quantum efficiency of the image sensors including CDTI structures with the four-quadrant square shape and the Union Jack shape have been listed and described in embodiment 1, which will not be repeated here.

As described, in the structure and method for improving the near-infrared quantum efficiency of the backside illuminated image sensor provided by the present application, the structure at least includes a substrate 1 and a plurality of photodiodes 2. The photodiodes 2 are formed in the substrate 1. A cell deep trench isolation structure 3 is fabricated on a surface of each photodiode 2. The cross section of the cell deep trench isolation structure 3 parallel to the surface of said photodiode comprises one or both of a four-quadrant square shape and a Union Jack shape. In the present application, by fabricating the cell deep trench isolation structure 3 on the surface of the photodiode 2, the cell deep trench isolation structure 3 can increase the scattering of light in the photodiode 2, thus improving the optical path, increasing the absorption of incident light, especially near-infrared light, and greatly improving the quantum efficiency and photographing quality of the product.

Therefore, the present application effectively overcomes various disadvantages in the existing technology and has a high industrial utilization value.

The above embodiments are only used for exemplarily describing the principle and effect of the present application, instead of limiting the present application. Those skilled in the art may modify or change the above embodiments without departing from the spirit and scope of the present application. Therefore, all equivalent modifications or changes made by those with ordinary knowledge in the technical field without departing from the spirit and technical concept disclosed in the present application should still be covered by the claims of the present application.

What is claimed is:

1. A structure for improving near-infrared quantum efficiency of a backside illuminated image sensor, wherein the structure at least comprises a substrate and a plurality of photodiodes, wherein the plurality of photodiodes is formed in the substrate, and wherein a cell deep trench isolation structure is fabricated on a surface of each of the plurality of photodiodes.

2. The structure for improving the near-infrared quantum efficiency of the backside illuminated image sensor according to claim 1, wherein a cross section of the cell deep trench isolation structure parallel to the surface of said photodiode comprises one or both of a four-quadrant square shape and a Union Jack shape.

3. The structure for improving the near-infrared quantum efficiency of the backside illuminated image sensor according to claim 1, wherein a depth of the cell deep trench isolation structure is between 0.3 μm and 1.5 μm, and a critical dimension is between 100 nm and 200 nm.

4. The structure for improving the near-infrared quantum efficiency of the backside illuminated image sensor according to claim 1, wherein the of the plurality of photodiodes are isolated by a deep trench isolation region, and the depth of the cell deep trench isolation structure is less than a depth of the deep trench isolation region.

5. The structure for improving the near-infrared quantum efficiency of the backside illuminated image sensor according to claim 1, wherein the structure further comprises a color filter and a micro lens sequentially disposed on one surface of each of the plurality of photodiodes, and a metal wire structure located on another surface of said photodiode.

6. A method for improving near-infrared quantum efficiency of a backside illuminated image sensor, wherein the method at least comprises:
providing a substrate and fabricating a plurality of photodiodes in the substrate; and
fabricating a cell deep trench isolation structure on a surface of each of the plurality of photodiodes.

7. The method for improving the near-infrared quantum efficiency of the backside illuminated image sensor according to claim 6, wherein a cross section of the cell deep trench isolation structure parallel to the surface of said photodiode comprises one or both of a four-quadrant square shape and a Union Jack shape.

8. The method for improving the near-infrared quantum efficiency of the backside illuminated image sensor according to claim 6, wherein a depth of the cell deep trench isolation structure is between 0.3 μm and 1.5 μm, and the critical dimension is between 100 nm and 200 nm.

9. The method for improving the near-infrared quantum efficiency of the backside illuminated image sensor according to claim 6, wherein the cell deep trench isolation structure is fabricated on the surface of each of the plurality of photodiodes by adopting photolithographic and etching processes.

10. The method for improving the near-infrared quantum efficiency of the backside illuminated image sensor according to claim 6, wherein the method further comprises a step of forming a deep trench isolation region between two adjacent ones of the plurality of photodiodes, and wherein a depth of the cell deep trench isolation structure is less than a depth of the deep trench isolation region.

11. The method for improving the near-infrared quantum efficiency of the backside illuminated image sensor according to claim 6, wherein the method further comprises:
sequentially forming a color filter and a micro lens on the surface of each of the plurality of photodiodes; and
forming a metal wire structure on another surface of each of the plurality of photodiodes.
